(19) United States
(12) Patent Application Publication
(10) Pub. No.: US 2015/0131075 A1
(43) Pub. Date: May 14, 2015

(54) DRAWING APPARATUS, AND METHOD OF MANUFACTURING ARTICLE

(71) Applicant: CANON KABUSHIKI KAISHA, Tokyo (JP)

(72) Inventors: Tatsuro KATO, Utsunomiya-shi (JP); Tomoyuki MORITA, Utsunomiya-shi (JP)

(21) Appl. No.: 14/527,233

(22) Filed: Oct. 29, 2014

(30) Foreign Application Priority Data
Nov. 12, 2013 (JP) 2013-234311

(51) Int. Cl. H01J 37/30; H01J 37/20

(52) U.S. Cl. CPC H01J 37/3002; H01J 37/20; H01J 2237/202; H01J 2237/31754
USPC 355/77; 250/396 R

(57) ABSTRACT

A drawing apparatus includes: a blanker; a deflector; a stage configured to hold the substrate and to be movable; and a controller configured to control the deflector and the stage so as to perform drawing by scanning the charged particle beam on the substrate by causing the deflector to deflect the charged particle beam in a first direction and moving the stage in a second direction. The controller is configured to cause the stage moving in the second direction to move in the first direction based on a pattern to be drawn and to control a scan width of the charged particle beam in the first direction by the deflector based on a moving amount of the stage in the first direction and the pattern.

### BACKGROUND OF THE INVENTION

1. Field of the Invention

The present invention relates to a drawing apparatus for performing drawing on a substrate with a charged particle beam, and a method of manufacturing an article.

2. Description of the Related Art

International Publication No. 2009-147202 discloses a drawing apparatus for performing drawing on a substrate with a plurality of charged particle beams (charged particle beam array) as a drawing apparatus used in the manufacture of devices such as semiconductor integrated circuits. The drawing apparatus disclosed in International Publication No. 2009-147202 performs drawing by moving the substrate in a direction perpendicular to the deflection direction of the plurality of charged particle beams while the charged particle beams are deflected and scanned on the substrate.

The drawing apparatus described in International Publication No. 2009-147202 draws a target pattern by deflecting each charged particle beam and controlling ON/OFF of irradiation of each charged particle beam in synchronism with deflection using drawing data. In the drawing apparatus described in International Publication No. 2009-147202, the scan width (deflection width) of the charged particle beam is a predetermined value set in advance, which is common to a plurality of shot regions. The scan width is set to a value compatible with all the plurality of shot regions. For this reason, the scan width of the charged particle beam is large, the drawing time is prolonged, and the throughput (productivity of devices) lowers.

The problem of a raster scan method has been described above. However, in a VSB drawing method serving as a vector method as well, when the scan width of a charged particle beam increases, the drawing time is prolonged. It can be done to reduce the deflection amount.

### SUMMARY OF THE INVENTION

The present invention provides, for example, a drawing apparatus advantageous in terms of throughput.

The present invention provide a drawing apparatus for performing drawing on a substrate with a charged particle beam, the apparatus comprising: a blanker configured to blank the charged particle beam; a deflector configured to deflect the charged particle beam to scan the charged particle beam on the substrate; a stage configured to hold the substrate and to be movable; and a controller configured to control the deflector and the stage so as to perform the drawing by scanning the charged particle beam on the substrate by causing the deflector to deflect the charged particle beam in a first direction and moving the stage in a second direction, wherein the controller is configured to cause the stage moving in the second direction to move in the first direction based on a pattern to be drawn and to control a scan width of the charged particle beam in the first direction by the deflector based on a moving amount of the stage in the first direction and the pattern.

Further features of the present invention will become apparent from the following description of exemplary embodiments with reference to the attached drawings.

### BRIEF DESCRIPTION OF THE DRAWINGS

FIG. 1 is a view showing an example of the arrangement of a drawing apparatus;

FIG. 2 is a view for explaining the drawing method of a raster scan method;

FIG. 3 is a view for explaining the positional relationship between a plurality of stripe drawing regions;

FIG. 4 is a view for explaining a method of drawing a shot array in an exposure region;

FIG. 5 is a view for explaining a method of drawing shots arrayed on a wafer;

FIGS. 6A to 6E are views for explaining a method of correcting deformed drawing responsible regions by adding correction regions;

FIGS. 7A and 7B are views for explaining a method of determining a deflection amount for a shot array unit;

FIG. 8 is a view for explaining a drawing method of a VSB drawing method; and

FIG. 9 is a view for explaining a method of determining a deflection amount in the VSB drawing method.

### DESCRIPTION OF THE EMBODIMENTS

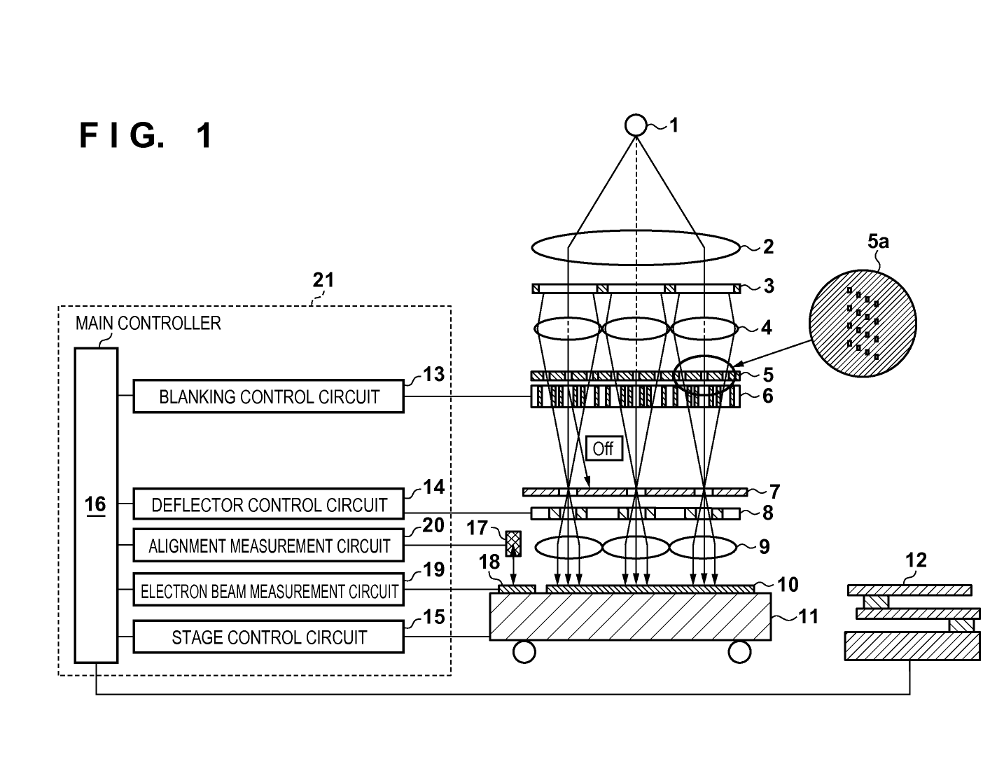

Embodiments of the present invention will be described below with reference to the accompanying drawings. FIG. 1 shows the arrangement of a drawing apparatus for performing drawing on a wafer (substrate) 10. Referring to FIG. 1, an electron source (charged particle source) 1 can use a so-called thermoelectronic or thermionic emission electron source containing LaB₆ or BaO/W (dispenser cathode) as an electron emitting material. A collimator lens 2 can use an electrostatic lens for converging an electron beam by an electric field. The electron beam emitted from the electron source 1 is collimated by the collimator lens 2 into a nearly parallel beam. Note that the drawing apparatus of this embodiment draws a pattern on a substrate with a plurality of electron beams, but can use another charged particle beam such as an ion beam in place of the electron beam. The drawing apparatus of this embodiment can be generalized as a drawing apparatus for drawing a pattern on a substrate with a plurality of charged electron beams.

An aperture array 3 has two-dimensionally arrayed apertures. In a condenser lens array 4, electrostatic condenser lenses having the same optical power are two-dimensionally arrayed. A pattern aperture array 5 includes a pattern aperture array (subarray) which defines (determines) the shape of the electron beam and corresponds to each condenser lens. Reference numeral 5a indicates a shape when the subarray is viewed from the above.

The nearly parallel electron beam from the collimator lens 2 is divided into a plurality of electron beams by the aperture array 3. Each divided electron beam irradiates the subarray of the corresponding pattern aperture array 5 through the corresponding condenser lens of the condenser lens array 4. The aperture array 3 has a function of defining an irradiation range.

A blanker array 6 includes a plurality of individually drivable electrostatic blankers (electrode pairs) each corresponding to each condenser lens. In the blanking aperture array 7, a blanking aperture (one aperture) is arranged in correspondence with each condenser lens. The blanker array 6 and the blanking aperture array 7 blank the charged particle beam. A deflector array 8 includes a plurality of deflectors each deflecting the electron beam in a predetermined direction and corresponding to each condenser lens. In an objective lens array 9, electrostatic objective lenses are arrayed in correspondence with the respective condenser lenses. The components from the electron source 1 to the blanking aperture array 7 and the objective lens array 9 constitute a projection system for irradiating the wafer 10 with the electron beams. The irradiation system from the electron source 1 to the blanking aperture array 7, the projection system of the objective lens array 9, and the deflection array 8 constitute an electron optical system (charged particle optical system).

The electron beam emerging from each subarray of the pattern aperture array 5 is reduced into 1/100 through the corresponding blanker, blanking aperture, deflector, and objective lens and is projected onto the wafer 10. The following relationship is given. That is, a plane on which the pattern apertures are arrayed in the subarray serves as an object plane, and the upper surface of the wafer 10 serves as an image plane.

Under the control of the corresponding blanker, the electron beam from each subarray of the pattern aperture array 5 is switched whether the electron beam is shielded by the blanking aperture, that is, whether the electron beam enters the wafer 10. In parallel with this, the electron beams entering the wafer 10 are scanned on the wafer 10 while being deflected at once at a predetermined deflection width by the deflector array 8.

The electron source 1 is formed into an image on the blanking aperture through the collimator lens 2 and the condenser lens. The size of the image is set to be larger than the size of the blanking aperture. The semiangle of the electron beam on the wafer 10 is defined by the blanking aperture. The blanking aperture is located at the front-side focal position of the corresponding objective lens. For this reason, the principal rays of the plurality of electron beams emerging from the plurality of pattern apertures of the subarray enter on the wafer 10 substantially vertically. For this reason, even if the upper surface of the wafer 10 displaces vertically, the displacement of the electron beams on the horizontal plane is small.

An X-Y stage (stage) 11 holds the wafer 10 and is movable within the X-Y plane (horizontal plane) perpendicular to the optical axis. The stage 11 includes a chuck mechanism (not shown) such as an electrostatic chuck for holding (attracting) the wafer 10. The stage 11 has a reference mark 18 including an alignment mark and a detector for detecting the position of the electron beam. The detector includes an aperture pattern which receives an electron beam. An alignment scope 17 aligns and measures the position of the reference mark 18 and the position of the underlying pattern patterned on the wafer 10 in advance. A conveyance mechanism 12 conveys the wafer 10 and transfers the wafer 10 with the stage 11. The alignment scope 17 is configured as a measuring device for measuring the positions of the shot regions forming an array.

A blanking control circuit 13 individually controls a plurality of blankers of the blanker array 6. A deflector control circuit 14 controls the plurality of deflectors of the deflector array 8 using a common signal. A stage control circuit 15 cooperates with a laser interferometer (not shown) for measuring the position of the stage 11 to position the stage 11. An electron beam measuring circuit 19 controls the detector included in the reference mark 18 to detect the position of the electron beam and controls the measurement of the position of the electron beam. An alignment measuring circuit 20 controls the alignment scope 17 and controls to measure the position of the reference mark 18 and the position of the alignment mark position of the underlying mark patterned on the wafer 10 in advance. A main controller 16 controls the plurality of control circuits described above and comprehensively controls the drawing apparatus. Note that a controller 21 of the drawing apparatus includes the control circuits 13 to 15, the measuring circuits 19 and 20, and the main controller 16 of this embodiment. This is merely an example, and can be variously changed.

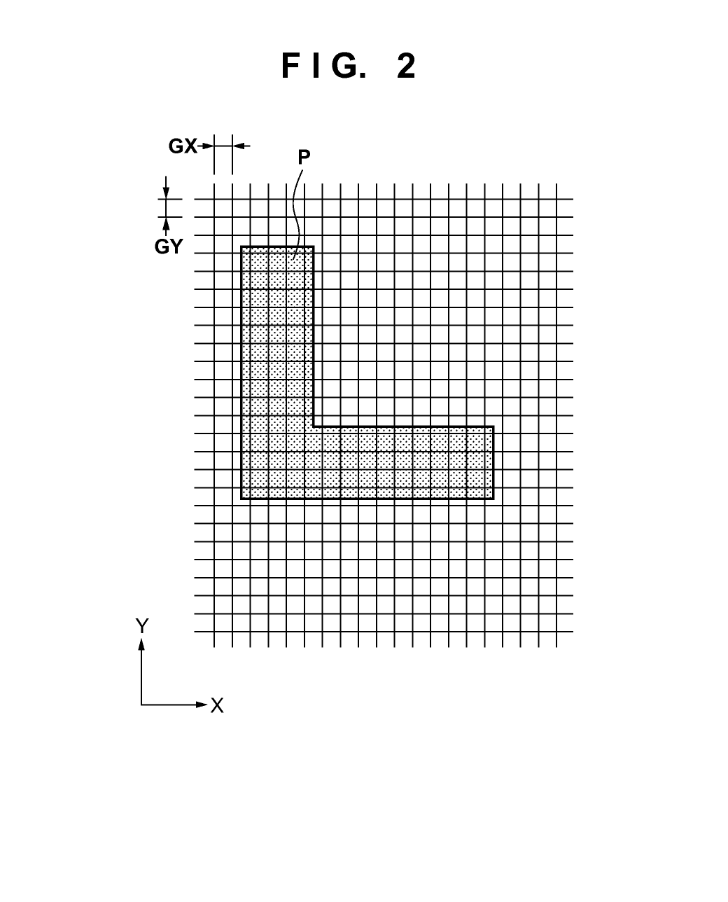

The drawing method of the raster scan method according to this embodiment will be described with reference to FIG. 2. The blanker array 6 controls the irradiation (ON state) and non-irradiation (OFF state) on the wafer 10 in accordance with a drawing pattern P while the electron beam is scanned on the scanning grid on the wafer 10 which is determined in accordance with the deflection by the deflector array 8 and the position of the stage 11. As shown in FIG. 2, the scanning grid is a grid formed by a pitch GX in the X direction and a pitch GY in the Y direction. The irradiation and non-irradiation of the electron beam is assigned to an intersection (grid point) between the vertical and horizontal lines in FIG. 2.

The controller 21 controls, for each grid point defined by the grid pitch GX, the irradiation and non-irradiation of each electron beam by scanning each electron beam in the X direction (first direction) while the wafer 10 is continuously moved by the stage 11 in the Y direction (second direction). The controller 21 scans each electron beam in the X direction, and then performs drawing by sequentially repeating scanning of each electron beam in the X direction through the flyback in the Y direction. In each subarray, drawing is performed for a stripe drawing region SA having a stripe width SW.

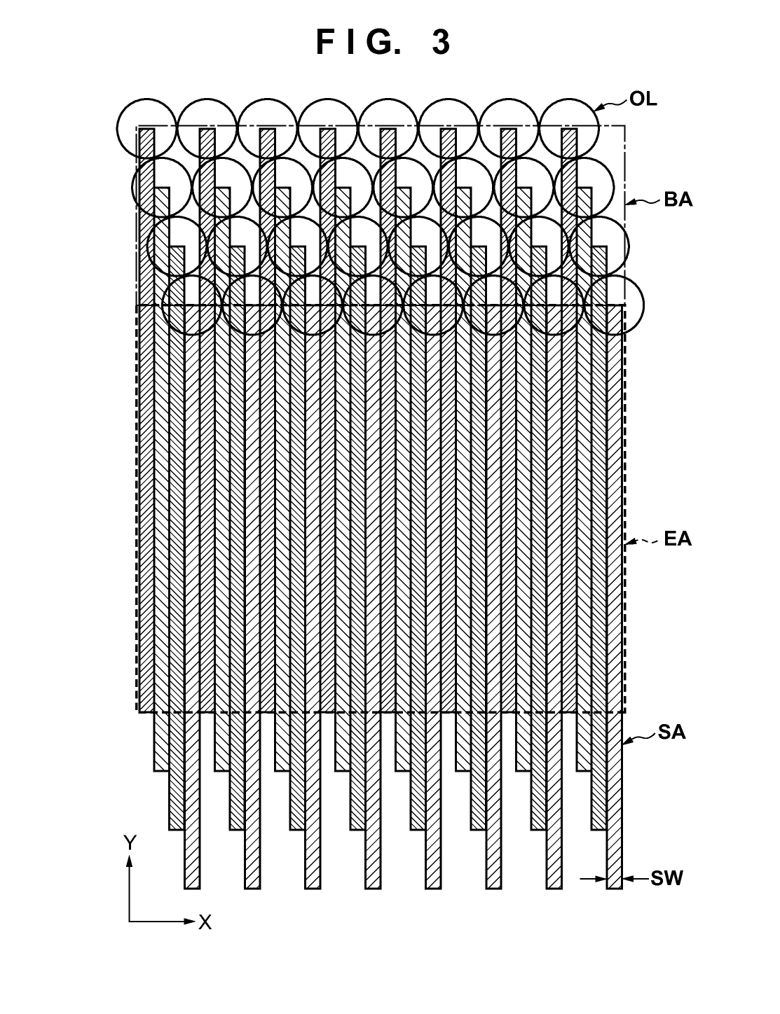

FIG. 3 will explain the positional relationship between the plurality of stripe drawing regions SA per subarray (or objective lens OL). When the objective lens array 9 is an objective lens array (including a total of 12,960 objective lenses) of 72 rows×180 columns, the objective lenses OL are one-dimensionally arrayed at a pitch of 144 μm in the X direction. The objective lenses OL of the next row are displaced by 2 μm in the X direction so as to make the stripe drawing regions SA having the stripe width SW (2 μm) adjacent to each other. For the sake of descriptive convenience, an objective lens array of 4 rows×8 columns is illustrated in FIG. 3. With this arrangement, the stage 11 is continuously moved (scanned) in one direction along the Y direction to perform drawing in an exposure region EA on the wafer 10.

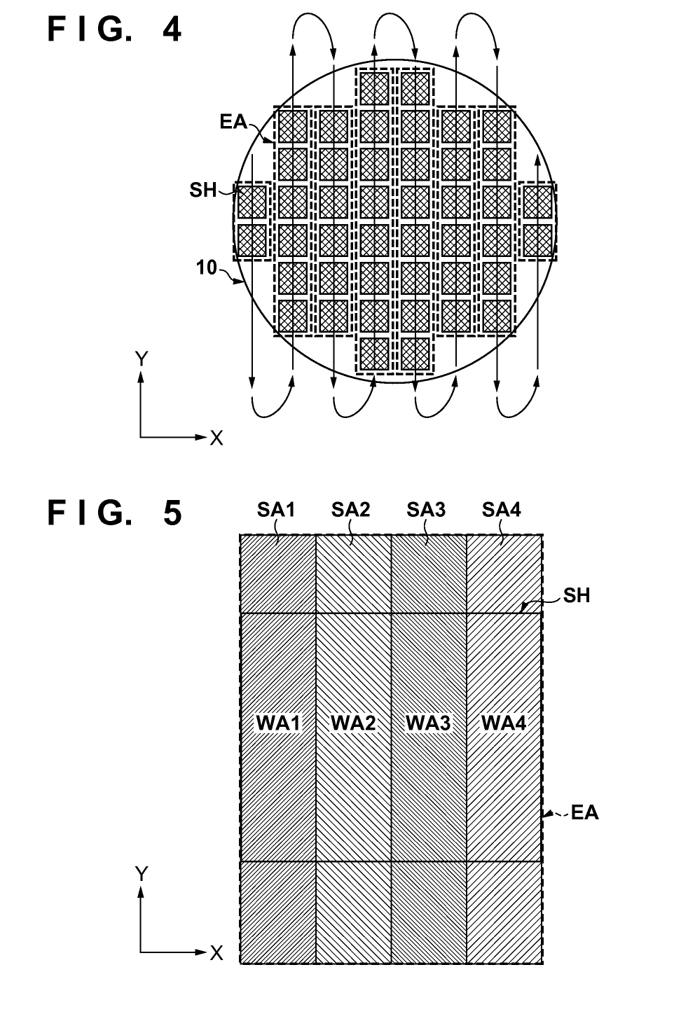

FIG. 4 explains a method of performing drawing on a plurality of shot regions SH two-dimensionally arranged on the wafer 10 in the exposure region EA serving as an aggregate of the stripe drawing regions SA. The shot region SH is a unit of drawing. Drawing data is handled and processed in this unit, thereby performing drawing. Note that matching between the size of the shot region SH and the size (26 mm×33 mm) of the shot region of the optical exposure apparatus can be used for the mix-and-match process with the optical exposure apparatus.

The shot regions SH are arranged on the wafer 10 in an array along the Y direction so as to include the shot regions SH in the exposure region EA. The stage 11 is continuously moved (scanned) in the Y direction to allow drawing of the shot regions SH. When the drawing region EA includes stripe drawing regions SA having the stripe width SW (2 μm) in the objective lens array including, for example, the total of 12,960 objective lenses, the width of the drawing region EA becomes 25.92 mm. By repeating scanning as indicated by arrows while turning scanning for each shot array, drawing of all the shot regions SH arranged on the wafer 10 is performed.

If the drawing shapes of the shot regions SH arrayed on the wafer 10 are the same, the same drawing data can be repeatedly used. This makes it possible to reduce the time for handling the drawing data, resulting in an advantage in production capability. FIG. 4 exemplifies a case in which the exposure region EA has a sufficiently large width and can include the size of the shot region of the optical exposure apparatus. However, even if the width of the exposure region EA is smaller than that of the shot region SH, drawing can be performed. In this case, the shot region SH is divided by the exposure region EA into adjacent regions, and drawing is sequentially performed for each divided region.

FIG. 5 explains the relationship between the shot region SH and the stripe drawing region SA forming the exposure region EA. FIG. 3 explains the case in which 32 (an array of 4 (rows)×8 (columns) objective lenses) stripe drawing regions SA form the exposure region EA. For the sake of descriptive convenience, FIG. 5 shows that one shot region SH is formed from the four stripe drawing regions SA, that is, SA1 to SA4. The shot region SH is divided by the stripe drawing regions SA1 to SA4 along the Y direction. Each stripe drawing region is divided as drawing responsible regions WA1 to WA4, and drawing is repeatedly performed for each shot array along the Y direction. In the following description, the shot region SH is formed from the four stripe drawing regions SA1 to SA4 and the drawing responsible regions WA1 to WA4, unless otherwise specified.

[Shape Correction by Adding Correction Region]

When drawing is performed for each shot region SH, an error actually occurs due to an error of an electron beam and distortion of an underlying shot region. The error of the electron beam is a displacement of the electron beam irradiation position from the target position on the substrate, which displacement is caused by an error of an electron optical system. The distortion information of the underlying shot region is obtained in alignment measurement by the alignment scope 17, and correction amounts for the distortion of the shot region are given by equation (1). Xs and Ys are arbitrary drawing coordinates in the shot coordinate system having the center of the shot region as an origin, dXs and dYs are correction amounts in the drawing coordinates, and Ax, Bx, Cx, Dx, Ay, By, Cy, and Dy are shot shape correction coefficients.

$$( \begin{matrix}dXs \\ dYs\end{matrix} ) = ( \begin{matrix}Ax Bx Cx Dx \\ Ay By Cy Dy\end{matrix} ) \cdot [ \begin{matrix}Xs \\ Ys \\ Xs \cdot Ys \\ 1\end{matrix} ] \qquad ( 1 )$$

The displacement of the electron beam irradiation position which is caused by errors of the electron lens and deflector and contamination is generated mainly for each subarray (or objective lens OL). This displacement information is measured, in advance, by the electron beam measuring circuit 19 and the reference mark 18 as the average amounts of the subarray electron beams at the time of measurement of the electron beams and is given by equation (2). Xb and Yb are drawing coordinates obtained by transforming the shot coordinate system into each beam deflection coordinate system having the deflection center of each subarray as an origin in order to express the correction using the subarray (or objective lens OL) as a unit. dXn and dYn are correction amounts in drawing coordinates. Axn, Bxn, Cxn, Dxn, Ayn, Byn, Cyn, and Dyn are correction coefficients, and n represents a numerical value for discriminating the respective subarrays (or objective lenses OL).

$$( \begin{matrix}dXn \\ dYn\end{matrix} ) = ( \begin{matrix}Axn Bxn Cxn Dxn \\ Ayn Byn Cyn Dyn\end{matrix} ) \cdot [ \begin{matrix}Xb \\ Yb \\ Xb \cdot Yb \\ 1\end{matrix} ] \qquad ( 2 )$$

Drawing coordinates (Xs′, Ys′) obtained by correcting the error caused by the distortion of the underlying shot region and expressed by equation (1) and the error caused by the displacement of the electron beam irradiation position and expressed by equation (2) are given:

$$( \begin{matrix}{Xs}^{′} \\ {Ys}^{′}\end{matrix} ) = ( \begin{matrix}Xs + dXs + dXn \\ Ys + dYs + dYn\end{matrix} ) \qquad ( 3 )$$

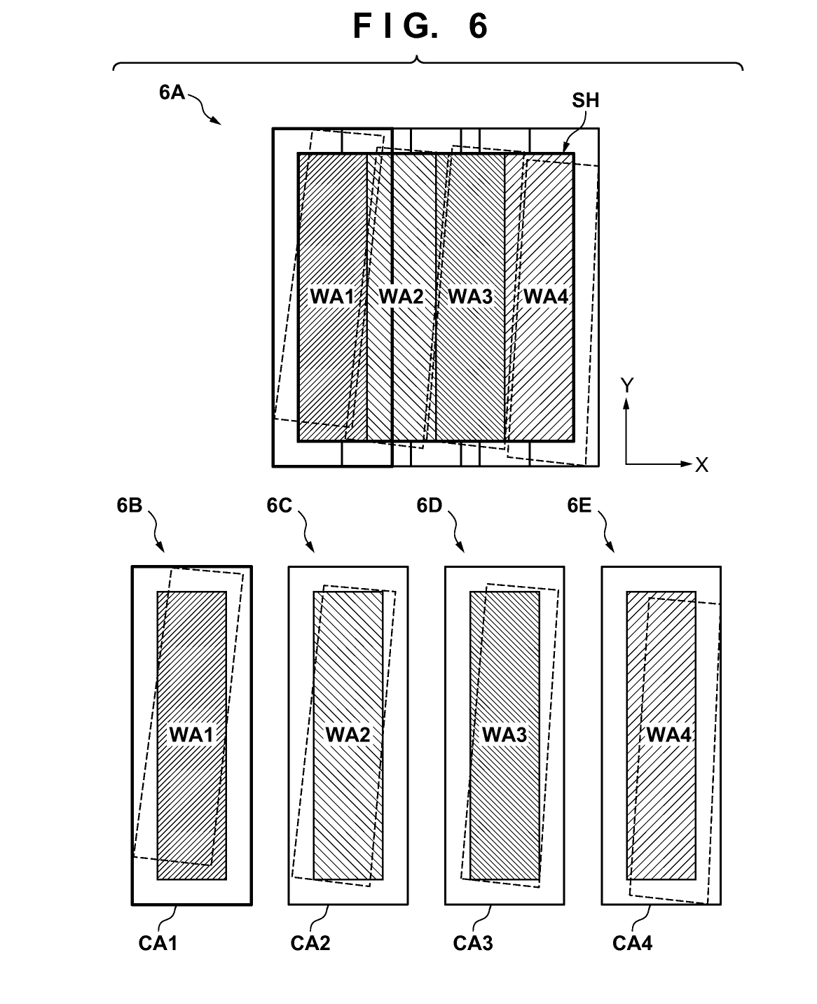

FIGS. 6A to 6E explain a method of performing drawing after adding correction regions CA1 to CA4 to the drawing responsible regions WA1 to WA4 whose positions and shapes are changed by errors of electron beams and errors of underlying shot regions. FIG. 6A shows a state in which the adjacent drawing responsible regions WA1 to WA4 and the corresponding correction regions CA1 to CA4 are arranged adjacent to each other as designed. FIGS. 6B to 6E show the drawing responsible regions WA1 to WA4 and their correction regions CA1 to CA4 in FIG. 6A separately so as to clearly illustrate the respective regions. The positions and shapes of the drawing responsible regions WA1 to WA4 forming the shot region SH are changed as indicated by broken lines as a result of correction by equation (3). Since drawing is performed upon compensating for the changes in positions and shapes, the controller 21 redundantly adds the correction regions CA1 to CA4 to the boundaries of the respective drawing responsible regions WA1 to WA4 and performs overscanning, thereby correcting the drawing data while widening the exposure region EA. FIG. 6B shows that a region obtained by adding CA1 is particularly indicated by a thick line. More specifically, in the X direction, the stripe width SW is increased to form an overlap between the adjacent stripe drawing regions. In the Y direction, the region is simply increased to add each of the correction regions CA1 to CA4.

The drawing data are corrected by equation (3) for the respective drawing responsible regions WA1 to WA4, and drawing is performed in regions including the correction regions CA1 to CA4. The scanning width (deflection width) of the correction region in the X direction must be increased to increase and assure the stripe width SW. The extended scanning width (time) is required to perform the correction, but is a useless width (time) from the viewpoint of productivity.

Conventionally, the correction region amount is set in advance by estimating a necessary correction region amount in consideration of each type of error amount serving as a correction target. However, in order to suppress the decrease in productivity while implementing the correction, the present invention adjusts a minimum amount necessary for actual correction of the correction region amount and determines the scanning width.

### First Embodiment

Drawing is performed on each of shot regions SH arrayed on a wafer 10, as shown in FIG. 4, by deflecting the electron beam in an X direction while continuously moving (scanning) the shot regions SH for each shot array in a Y direction and performing drawing in each stripe drawing region. In this case, the continuous moving (scanning) speed required for drawing of each stripe drawing region in the Y direction depends on the scanning width (time) of the electron beam in the X direction. The larger the scanning width (time) of the electron beam, the lower the speed; and vice versa. In order to simultaneously perform drawing of each stripe drawing region while scanning the shot regions with a stage 11 stably at a predetermined speed in the Y direction, the scanning width (time) of each stripe drawing region in the X direction must be kept at a common predetermined value for each shot array.

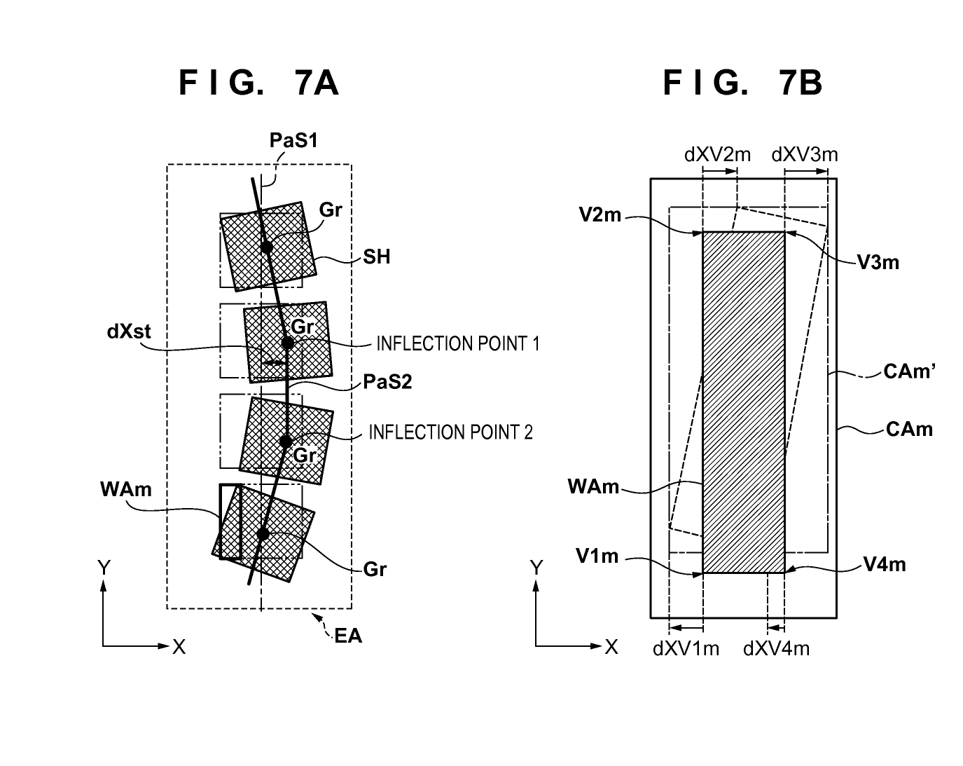

FIGS. 7A and 7B explain a method of causing the controller 21 to obtain a stage scan trajectory, calculate a correction region amount required for each shot array, and determine the scanning width. A track drawn on the wafer 10 by the barycentric position of the electron beam array projected on the wafer 10 in a state in which a deflector array 8 does not perform deflection when the stage 11 is driven is called a stage scan trajectory. A stage scan trajectory set to pass the X-direction central value of each shot region SH free from deformation is indicated by an alternate long and short dashed line PaS1 in FIG. 7A.

The arrangements and shapes of the shot regions SH of the shot array are actually different from each other, as shown in FIG. 7A and are acquired in an immediately preceding alignment measurement. An error of the electron beam occurs on a subarray (or objective lens OL) basis and is acquired by an immediately preceding electron beam measurement. First of all, the stage scan trajectory will be described below. As shown in FIG. 7A, barycentric coordinates Gr of each shot region SH of the shot array are obtained, and a straight line which connects the resultant barycentric coordinates Gr is defined as a stage scan trajectory PaS2. A deviation at a given Y-coordinate in the X direction between the stage scan trajectory PaS1 and the scan trajectory PaS2 is defined as dXst.

Next, a method of calculating a correction region amount required for each shot array and determining a scanning width when drawing on the shot region SH is performed with the stage scan trajectory PaS1 will be described below. The shot shape correction coefficient expressed by equation (1) changes for each shot region SH in the shot array. The electron beam correction coefficient expressed by equation (2) is updated by the immediately preceding electron beam measurement result. The correction amount (drawing coordinates after correction) expressed by equation (3) changes accordingly. That is, the correction amount (drawing coordinates after correction) expressed by equation (3) changes on the basis of drawing responsible regions WA1 to WA4 constituting each shot region SH. Actually required correction region amount changes accordingly. The scanning width in the X direction is adjusted, for each shot array, to a necessary minimum width which can include all correction region amounts having different necessary amounts, and drawing is then performed to reduce unnecessary deflection time.

More specifically, all X-direction correction deviation amounts necessary for the respective drawing responsible regions WA1 to WA4 of each shot region SH constituting the shot array are obtained. With reference to FIG. 7B, a method of obtaining the correction deviation amount of an arbitrary drawing responsible region WAm in an exposure region EA including the shot array will be described below. Note that WAm indicates an arbitrary drawing responsible region (m is a number for uniquely discriminating the respective drawing responsible regions). The region WAm deformed by various errors is indicated by a broken line. A region estimated in advance as a correction region is given as CAm, and a correction region optimized by an actual necessary correction amount is given as CAm′ (an alternate long and short dashed line).

The shape correction transformations expressed by equations (1) to (3) perform correction transformations from a quadrangle to a quadrangle. For this reason, necessary correction deviation amount can be obtained from four vertices V1m to V4m of the drawing responsible region WAm. The coordinates of the four vertices V1m to V4m of each drawing responsible region are transformed by equations (1) and (2), thereby obtaining correction deviations (dXs+dXn) from the X-coordinates before correction. The correction deviations of the four vertices V1m to V4m are defined as dXV1m, dXV2m, dXV3m, and dXV4m, respectively. The correction region amount of the drawing responsible region WAm in the negative X direction is a smaller one of dXV1m and dXV2m. The correction region amount of the drawing responsible region WAm in the positive X direction is a larger one of dXV3m and dXV4m. In the case of FIG. 7B, the correction region amount in the negative X direction is dXV1m (negative value), and the correction region amount in the positive X direction is dXV3m (positive value). In order to correct the shape of the drawing responsible region WAm in FIG. 7B and perform drawing, the scanning width in the X direction before correction is extended by −dXV1m in the negative direction, and by dXV3m in the positive direction. Therefore, the scanning width is increased by only (dXV3m−dXV1m).

The common scanning width for each shot array is similarly determined from the minimum value of the X-direction negative-side correction region amounts of all the drawing responsible regions WAm obtained as described above and the maximum value of the X-direction positive-side correction region amounts. That is, in order to correct the shape for each shot array and perform drawing, the X-direction scanning width before correction is extended up to the minimum value of the X-direction negative-side correction region amounts and up to the maximum value of the X-direction positive-side correction region amounts, thereby determining the scanning width.

Next, a method of calculating a necessary correction region amount for a shot array and determining a scanning width when drawing is performed for the shot region SH with the stage scan trajectory PaS2 will be described below. As for the stage scan trajectory PaS1, the coordinates of the four vertices V1m to V4m of the drawing responsible region WAm are transformed by equations (1) and (2) to obtain the correction deviations (dXs+dXn). As for the stage scan trajectory PaS2, in addition to the four vertices of WAm, peripheral Y-coordinates of WAm at an inflection point must be taken into consideration if the inflection point is present on the stage scan trajectory PaS2 in the Y-direction range of the drawing responsible region WAm. As for the correction deviation, a correction deviation (dXs+dXn+dXst) including the deviation dXst between the stage scan trajectory PaS1 and the scan trajectory PaS2 described above is obtained. The deviation dXst indicates the moving amount of the stage 11 in the X direction (first direction). After the correction deviation (dXs+dXn+dXst) for the coordinates of the four vertices and the peripheral coordinates is obtained, the scanning width can be obtained in the same manner as in the stage scan trajectory PaS1.

In the first embodiment, the stage scan trajectory PaS2 is obtained by connecting the barycentric coordinates of the underlying shot regions SH by straight lines. However, the stage scan trajectory PaS2 may be obtained by collinear approximation or curve fitting. The barycentric coordinates are obtained for each underlying shot region. However, the underlying shot region is decomposed into a plurality of regions, and then barycentric coordinates are then obtained. In the first embodiment, the stage 11 is moved in only the X and Y directions, but can be driven in the rotational direction. If the uniform positional displacement occurs in the electron beams, the stage scan trajectory may be offset in accordance with the positional displacement amount.

### Second Embodiment

The first embodiment has exemplified the raster scan method. A drawing method (VSB method) using a variable shaped electron beam is proposed as a vector scan method. According to the VSB drawing method, a drawing pattern is divided into rectangular figures, and the shape of the electron beam is divided into rectangles, thereby performing drawing. The operation of the VSB drawing method will be described below.

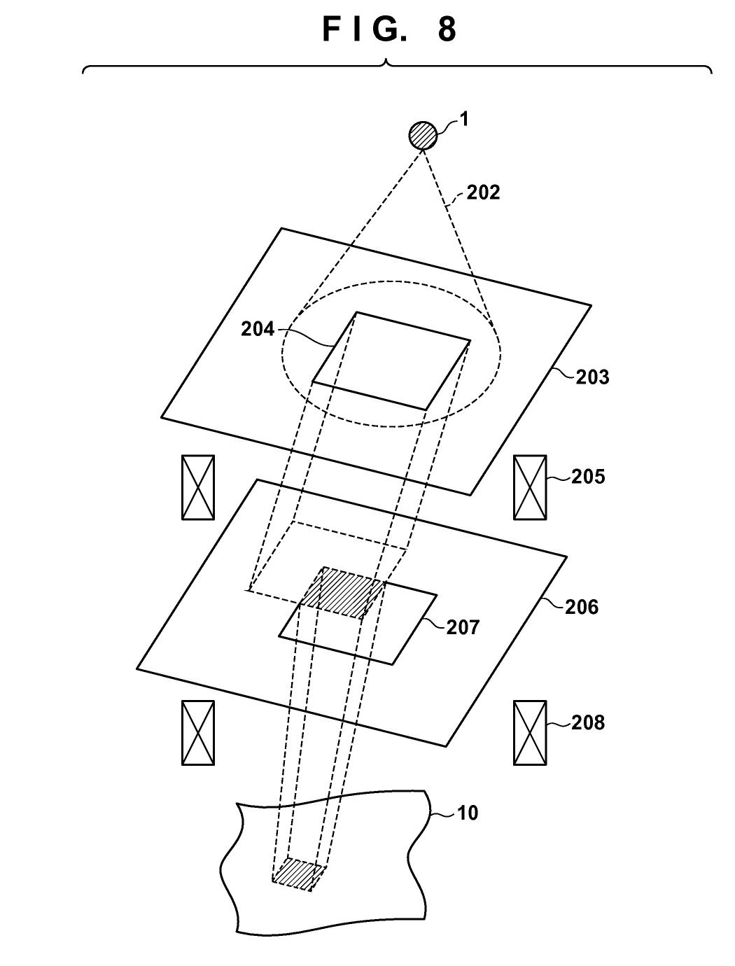

FIG. 8 explains the VSB drawing method. An electron beam 202 emitted from an electron source 1 passes through a first aperture unit 203. A first aperture 204 having a rectangular shape is formed in the first aperture unit 203 and forms the electron beam 202 into a rectangular shape. The electron beam 202 having passed through the first aperture unit 203 is deflected by a first deflector 205 and irradiates a second aperture unit 206. A second aperture 207 for shaping the electron beam into a predetermined rectangular shape is formed in the second aperture unit 206. The electron beam 202 having passed through the second aperture unit 206 is deflected by a second deflector 208 and irradiates a wafer 10 placed a continuously moving stage. The drawing pattern is divided into rectangular figures having various sizes, and drawing is then performed to form a drawing pattern by the aggregate of rectangular figures.

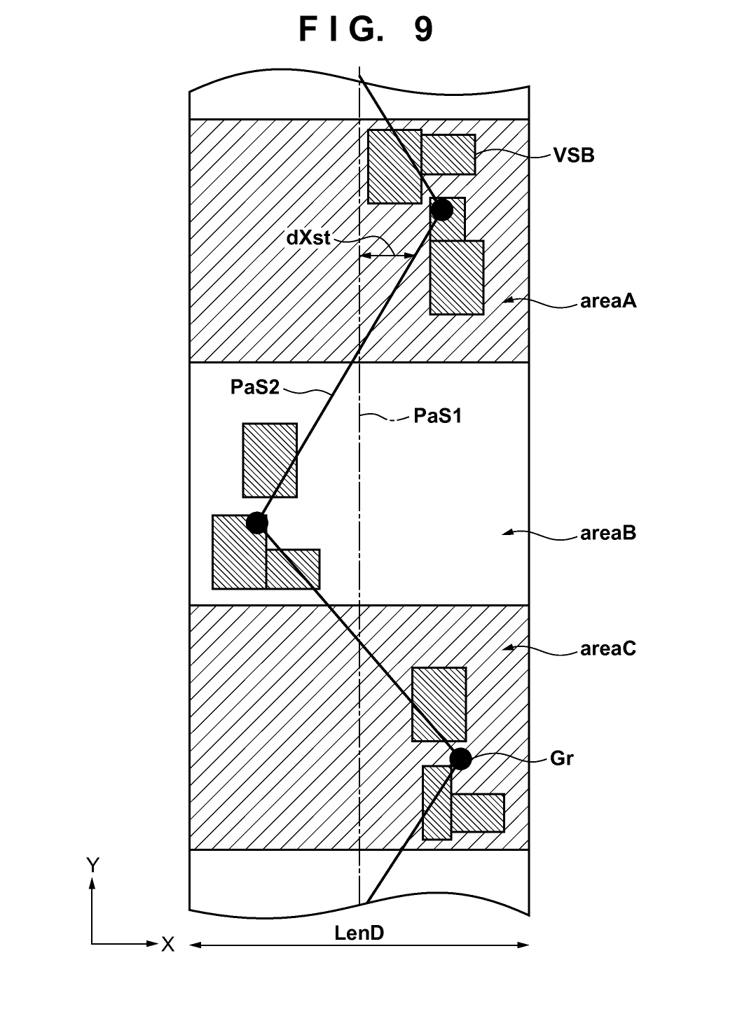

FIG. 9 shows part of the drawing region on the wafer 10. The respective figures indicated by VSB shots are obtained by dividing the drawing pattern formed on the wafer 10 into rectangular figures. A stage 11 is continuously driven along a stage scan trajectory PaS1 indicated by an alternate long and short dashed line. The electron beam 202 is deflected to sequentially perform drawing on the VSB shots falling within a LenD range deflectable by the second deflector 208. When the scanning width is large between the VSB shots subjected to sequential drawing, the settling time of the deflector is prolonged to lower the productivity. The scanning width can be narrow.

First of all, as shown in FIG. 9, the drawing region is divided into areaA, areaB, and areaC. The central value of the drawing patterns included in each region obtained by division is calculated for each region based on the drawing pattern design information. Straight lines which connect the calculated central values represent a stage scan trajectory PaS2 indicated by the solid line in FIG. 9. An X-direction deviation at a given Y-coordinate between the stage scan trajectory PaS1 and the scan trajectory PaS2 is defined as dXst. The drawing coordinates for the stage scan trajectory PaS2 are changed by dXst from the drawing coordinates of the scan trajectory PaS1 in the X direction. When the stage scan trajectory is given as PaS2, and drawing is performed to suppress the scanning width of the deflector.

[Article Manufacturing Method]

An article manufacturing method according to an embodiment of the present invention is suitable for manufacturing a microdevice such as a semiconductor device, and an article such as an element having a microstructure. This manufacturing method can include a step of forming a latent image pattern on a photosensitive agent applied to a substrate by using the aforementioned lithography apparatus (step of forming a pattern on a substrate), and a step of developing the substrate on which the latent image pattern is formed in the preceding step. Further, the manufacturing method can include other well-known steps (for example, oxidization, deposition, vapor deposition, doping, planarization, etching, resist removal, dicing, bonding, and packaging). The article manufacturing method according to the embodiment is superior to a conventional method in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-234311, filed Nov. 12, 2013, which is hereby incorporated by reference herein in its entirety.

What is claimed is:

1. A drawing apparatus for performing drawing on a substrate with a charged particle beam, the apparatus comprising:
a blanker configured to blank the charged particle beam;
a deflector configured to deflect the charged particle beam to scan the charged particle beam on the substrate;
a stage configured to hold the substrate and to be movable; and
a controller configured to control the deflector and the stage so as to perform the drawing by scanning the charged particle beam on the substrate by causing the deflector to deflect the charged particle beam in a first direction and moving the stage in a second direction,
wherein the controller is configured to cause the stage moving in the second direction to move in the first direction based on a pattern to be drawn and to control a scan width of the charged particle beam in the first direction by the deflector based on a moving amount of the stage in the first direction and the pattern.

2. The apparatus according to 1, wherein the controller is configured to control the deflector and the stage so as to perform the drawing with respect to each array of shot regions arranged in the second direction.

3. The apparatus according to claim 2, wherein the controller is configured to determine the moving amount based on a position of a shot region constituting the array.

4. The apparatus according to claim 3, further comprising a measuring device configured to measure the position.

5. The apparatus according to claim 3, wherein the controller is configured to determine a trajectory of the stage based on a position of each shot region constituting the array.

6. The apparatus according to claim 5, wherein the controller is configured to determine the trajectory of the stage as one of a curve and a straight line.

7. The apparatus according to claim 1, wherein the controller is configured to determine the moving amount based on design information of the pattern.

8. The apparatus according to claim 1, wherein the controller is configured to determine the scan width further based on a displacement of a position of the charged particle beam on the substrate from a target position.

9. The apparatus according to claim 1, wherein the drawing apparatus is configured to perform drawing on the substrate with a plurality of charged particle beams arranged at an interval in the first direction on the substrate,
the drawing apparatus comprise a plurality of the blanker and a plurality of the deflector, and
the controller is configured to control the plurality of the deflector so that the plurality of the deflector have a common scan width.

10. A method of manufacturing an article, the method comprising steps of:
performing drawing on a substrate using a drawing apparatus; and
processing the substrate having undergone the drawing to manufacture the article,
wherein the drawing apparatus performs drawing on the substrate with a charged particle beam, and includes:
a blanker configured to blank the charged particle beam;
a deflector configured to deflect the charged particle beam to scan the charged particle beam on the substrate;
a stage configured to hold the substrate and to be movable; and
a controller configured to control the deflector and the stage so as to perform the drawing by scanning the charged particle beam on the substrate by causing the deflector to deflect the charged particle beam in a first direction and moving the stage in a second direction,
wherein the controller is configured to cause the stage moving in the second direction to move in the first direction based on a pattern to be drawn and to control a scan width of the charged particle beam in the first direction by the deflector based on a moving amount of the stage in the first direction and the pattern.
